(19) United States
(12) Patent Application Publication
(10) Pub. No.: US 2026/0068617 A1
(43) Pub. Date: Mar. 5, 2026

(54) METHOD FOR FORMING INTERCONNECT STRUCTURE

(71) Applicant: Tokyo Electron Limited, Tokyo (JP)

(72) Inventors: Hirokazu Aizawa, Albany, NY (US); Kai-Hung Yu, Albany, NY (US)

(21) Appl. No.: 18/821,482

(22) Filed: Aug. 30, 2024

(51) Int. Cl. H01L 21/768; H01L 21/311; H01L 21/3205; H01L 21/3213

(52) U.S. Cl. CPC H01L 21/76883

(57) ABSTRACT

A method for forming an interconnect structure includes filling a hole through a dielectric layer with ruthenium using a deposition-etch-deposition (DED) process, forming a ruthenium layer over the dielectric layer, and forming a conductive feature from the ruthenium layer with a subtractive process. One or more etch steps of the DED process remove isolated ruthenium nuclei deposited over the dielectric layer by deposition steps of the DED process.

### TECHNICAL FIELD

The present invention relates generally to the field of semiconductor manufacturing, and specifically to methods for forming interconnect structures.

### BACKGROUND

Generally, a semiconductor device, such as an integrated circuit (IC) is fabricated by sequentially depositing and patterning layers of dielectric, conductive, and semiconductor materials over a substrate to form a network of electronic components and interconnect elements (e.g., transistors, resistors, capacitors, metal lines, contacts, and vias) integrated in a monolithic structure. Process flows used to form the constituent structures of semiconductor devices often involve depositing and removing a variety of materials while a pattern of several materials may be exposed in a surface of the working substrate.

The minimum dimension of features in a patterned layer is shrunk periodically to roughly double the component density at each successive technology node, thereby reducing the cost per function. Innovations in patterning, such as immersion deep ultraviolet (i-DUV) lithography, multi patterning, and 13.5 nm wavelength extreme ultraviolet (EUV) optical systems have brought some critical dimensions down to near ten nanometers. In advanced semiconductor devices, ruthenium has emerged as a promising material for interconnects due to its favorable electrical and physical properties. However, the formation of via structures in Ru subtractive interconnects may pose significant challenges.

### SUMMARY

In accordance with an embodiment, a method for forming an interconnect structure includes: filling a hole through a dielectric layer with ruthenium using a deposition-etch-deposition (DED) process, one or more etch steps of the DED process removing isolated ruthenium nuclei deposited over the dielectric layer by deposition steps of the DED process; forming a ruthenium layer over the dielectric layer; and forming a conductive feature from the ruthenium layer with a subtractive process.

In accordance with another embodiment, a method for forming an interconnect structure includes: etching an opening through a dielectric layer, the opening exposing a top surface of a first conductive feature; depositing ruthenium in the opening with a first chemical vapor deposition (CVD) step, the first CVD step further depositing ruthenium clusters over the dielectric layer; removing the ruthenium clusters with a first etch step; filling the opening with ruthenium with a later CVD step; performing a deposition of a ruthenium layer over the dielectric layer; and forming a second conductive feature from the ruthenium layer with a patterning process, the second conductive feature being over the filled opening.

In accordance with yet another embodiment, a method for forming an interconnect structure includes: forming a hole through a dielectric layer, a bottom surface of the hole being a top surface of a first conductive feature; filling the hole with ruthenium using a deposition-etch-deposition (DED) process, the DED process including: forming a first ruthenium layer in the hole with an initial deposition step; and performing one or more cycles of an etch and deposition process, each cycle including: removing isolated ruthenium nuclei deposited on a top surface of the dielectric layer by a previous deposition step with an etch step; and forming an additional ruthenium layer over the first ruthenium layer in the hole with a deposition step; and forming a second conductive feature including ruthenium over the filled hole.

It is to be understood that both the foregoing general description and the following detailed description are exemplary and explanatory only and are not restrictive of the disclosure, as claimed.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1 through 12 illustrate cross-sectional views of a semiconductor structure at intermediate stages of a semiconductor manufacturing process, in accordance with some embodiments;

FIGS. 13 through 17 illustrates cross-sectional views of another semiconductor structure at intermediate stages of a semiconductor manufacturing process, in accordance with some embodiments;

FIG. 18 illustrates a process flow chart diagram of a method for forming an interconnect structure, in accordance with some embodiments;

FIG. 19 illustrates a process flow chart diagram of a method for forming an interconnect structure, in accordance with some embodiments; and

FIG. 20 illustrates a process flow chart diagram of a method for forming an interconnect structure, in accordance with some embodiments.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

Ruthenium metal is attractive for use as interconnects in advanced applications, such as for reasons of low electrical resistivity and small electron mean-free-path. In particular, using ruthenium in conductive vias may allow for adhesion to underlying metal features without an intervening adhesion or liner layer, which may reduce electrical resistivity. However, use of ruthenium in the formation of via structures below subsequently formed subtractive interconnects (such as in semi-damascene processes) may pose significant challenges, particularly in maintaining wafer surface planarity when using conventional chemical mechanical polishing (CMP) techniques. Disclosed embodiments address these challenges by introducing a Deposition-Etch-Deposition (DED) process for via filling in a semi-damascene scheme. This innovative approach may reduce or eliminate a need for a CMP step of ruthenium that has been traditionally used for wafer surface leveling in via formation.

The proposed method offers several advantages over existing techniques including improved control over wafer surface topology, such as in layouts without dummy structures. Furthermore, embodiments of this disclosure expand applications for ruthenium chemical vapor deposition (CVD) technology in semiconductor manufacturing processes. The following detailed description will elucidate the novel aspects of this integration scheme, its implementation in ruthenium subtractive interconnect fabrication, and the significant improvements it brings to the field of semiconductor device manufacturing.

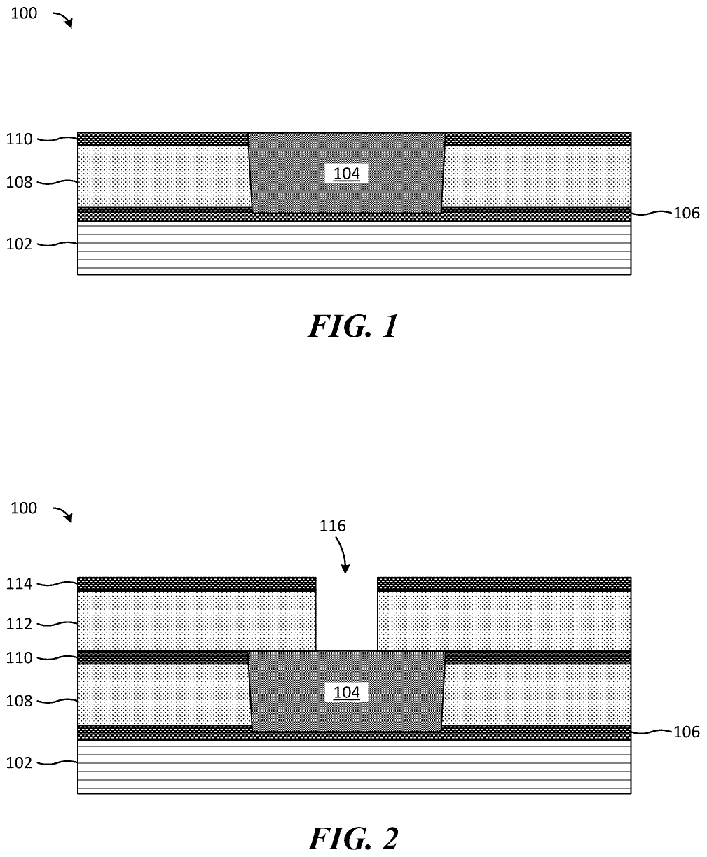

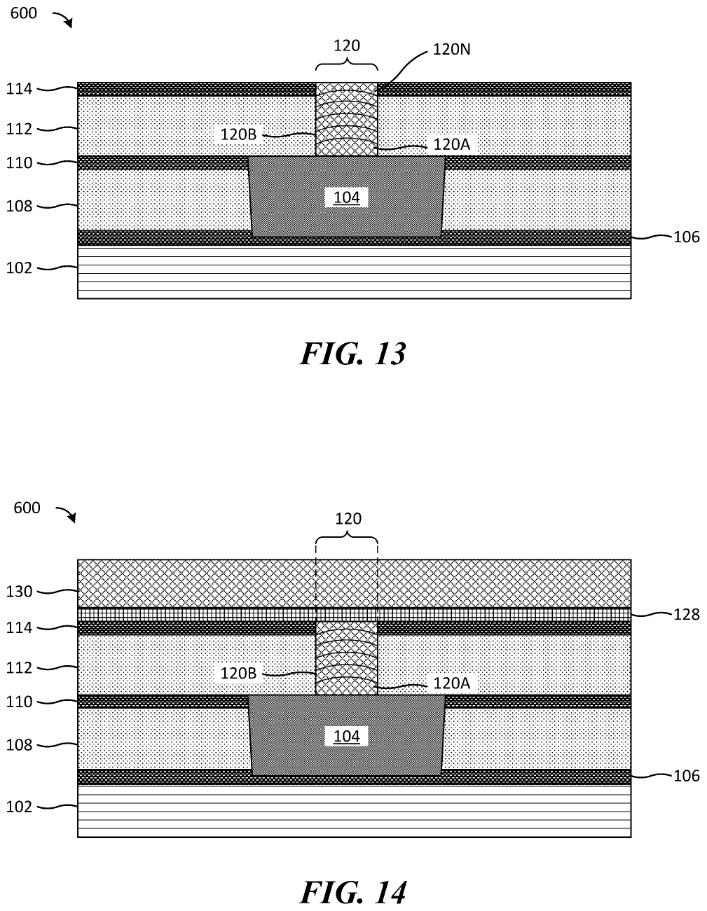

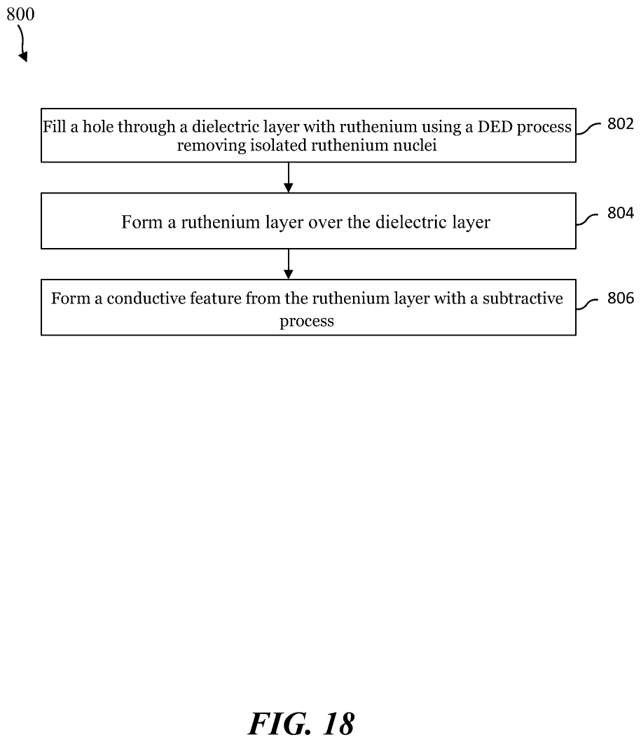

Embodiments of the disclosure are described in the context of the accompanying drawings. An embodiment of a method for manufacturing a via and overlying conductive feature will be described using FIGS. 1 through 12. An embodiment of another method for manufacturing a via and overlying conductive feature will be described using FIGS. 13 through 17. Embodiments of methods for forming interconnect structures will be described using FIGS. 18, 19, and 20.

FIGS. 1 through 12 illustrate cross-sectional views of a semiconductor structure 100 (also referred to as a substrate) at intermediate stages of a semiconductor manufacturing process, in accordance with some embodiments. As illustrated in FIG. 1, the semiconductor structure 100 includes a substrate 102, a first dielectric layer 108 over the substrate 102, a conductive feature 104 disposed in or through the first dielectric layer 108, and a first hardmask layer 110 over the first dielectric layer 108 and the conductive feature 104.

The substrate 102 may be a silicon wafer, such as a wafer having a diameter in a range of 100 mm to 500 mm, such as a diameter of 150 mm, 200 mm, 300 mm, or 450 mm. In various embodiments, the substrate 102 may be a part of, or include, a semiconductor device, and may have undergone a number of steps of processing following, for example, a conventional process. The substrate 102 accordingly may comprise layers of semiconductors useful in various microelectronics, such as various device regions.

In one or more embodiments, the substrate 102 may be a silicon wafer, or a silicon-on-insulator (SOI) wafer. In certain embodiments, the substrate 102 may comprise silicon germanium, silicon carbide, gallium arsenide, gallium nitride, or other compound semiconductors. In other embodiments, the substrate 102 comprises heterogeneous layers such as silicon germanium on silicon, gallium nitride on silicon, silicon carbon on silicon, as well as layers of silicon on a silicon or SOI substrate. In various embodiments, the substrate 102 is patterned or embedded in other components of the semiconductor device. In some embodiments, the substrate 102 comprises conductive features (e.g., metal lines, not illustrated) embedded therein. The conductive features may be electrically coupled to active devices (not illustrated) further embedded in the substrate 102.

The first dielectric layer 108 is over the substrate 102. In various embodiments, the first dielectric layer 108 comprises one or more insulators such as silicon dioxide (SiO₂) or a silicon oxide based low-k dielectric (e.g., porous oxides, fluorosilicate glass (FSG), and organosilicate glass (OSG)). In some embodiments, the first dielectric layer 108 is over a bottom layer 106 that is a hardmask layer or an etch stop layer (ESL) that comprises a dielectric such as Si₃N₄, SiOₓC_{y}N_{z}, SiC, SiOC, or SiCN.

In some embodiments, a first hardmask layer 110 is formed over the first dielectric layer 108. In various embodiments, the first hardmask layer 110 comprises titanium nitride, titanium, titanium oxide, tantalum, other tungsten based compounds, ruthenium based compounds, aluminum based compounds, amorphous silicon, the like, or a combination thereof. The first hardmask layer 110 may be formed with a spin-on process, CVD, ALD, the like, or a combination thereof. However, any suitable materials and methods may be used to form the first hardmask layer 110. In some embodiments, the first hardmask layer 110 further comprises a stop layer (not illustrated) as a top portion of the first hardmask layer 110. The stop layer may be used to stop a removal process (e.g., a chemical mechanical polish (CMP), etch back, or the like) of an overlying layer, such as excess conductive material formed over the first hardmask layer 110. In various embodiments, the stop layer comprises silicon nitride, silicon carbide, silicon oxynitride, silicon oxycarbide, silicon carbonitride, silicon oxycarbonitride, tungsten carbide, the like, or a combination thereof.

A conductive feature 104 (e.g., an underlayer metal feature such as a metal line and/or via) is formed into or through the first dielectric layer 108. The conductive feature 104 may couple with respective conductive features of the substrate 102. Although FIG. 1 illustrates one conductive feature 104, any suitable number of conductive features 104 may be formed in any suitable pattern or distribution in the semiconductor structure 100.

In some embodiments, the conductive feature 104 is formed with a damascene or dual damascene process. As an example, the first hardmask layer 110 is patterned with a suitable lithographic technique and the patterned first hardmask layer 110 is used as an etch mask to form an opening (e.g., a trench or hole) into or through the first dielectric layer 108. In some embodiments, the opening extends into the bottom layer 106. The opening is then filled with a conductive fill material. In various embodiments, the conductive fill material comprises one or more metals such as tungsten (W), ruthenium (Ru), copper (Cu), tin (Sn), titanium (Ti), hafnium (Hf), silver (Ag), gold (Au), cobalt (Co), nickel (Ni), molybdenum (Mb), niobium (Nb), tantalum (Ta), rhodium (Rh), iridium (Ir), palladium (Pd), indium (In), zinc (Zn), antimony (Sb), the like, or a combination thereof. The conductive fill material may be formed with any suitable technique, such as electroplating, electroless plating, or the like. Excess conductive material formed over the first hardmask layer 110 may be removed with a suitable planarization process, such as a CMP.

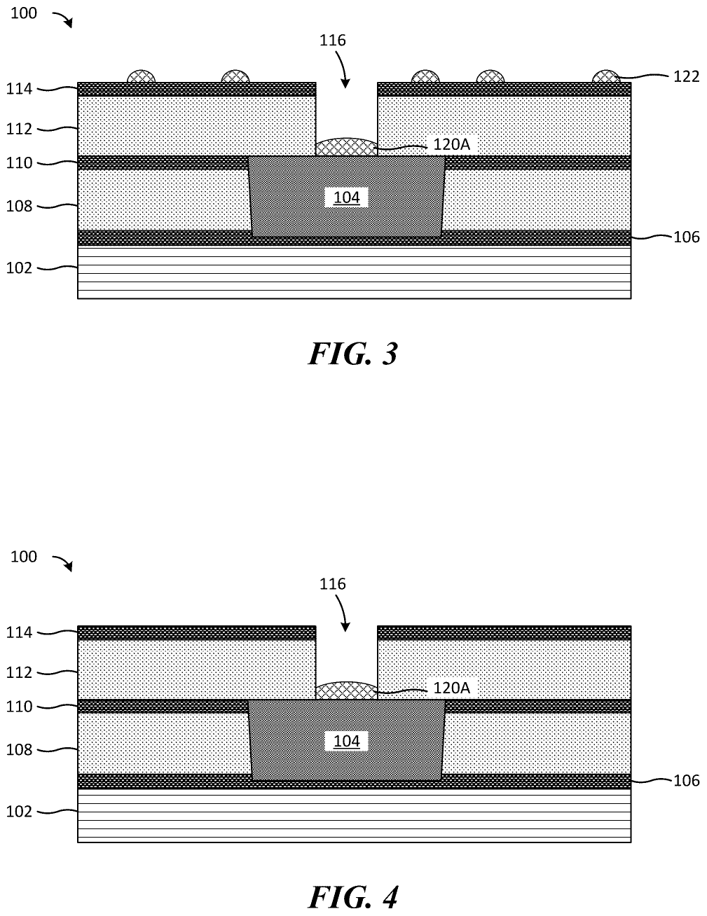

Next, in FIG. 2, a second dielectric layer 112 and a second hardmask layer 114 are formed over the conductive feature 104 and the first hardmask layer 110, and an opening 116 is formed through the second hardmask layer 114 and the second dielectric layer 112. The opening 116 will be subsequently filled with a conductive material (e.g., ruthenium) to form a conductive via (see below, FIGS. 3-7).

The second dielectric layer 112 may be formed using similar materials and methods as the first dielectric layer 108 as described above with respect to FIG. 1, and the details are not repeated herein. However, any suitable materials and methods may be used to form the second dielectric layer 112.

The second hardmask layer 114 may be formed using similar materials and methods as the first hardmask layer 110 as described above with respect to FIG. 1, and the details are not repeated herein. However, any suitable materials and methods may be used to form the second hardmask layer 114.

The opening 116 is formed through the second hardmask layer 114 and the second dielectric layer 112 to expose a top surface of the conductive feature 104. In various embodiments, the opening 116 is formed using conventional photolithography and etching techniques. As an example, a photoresist layer (not illustrated) is deposited over the second hardmask layer 114. In some embodiments, the photoresist layer is a trilayer photoresist with a bottom organic (ODL) layer, a middle antireflective coat layer, and a top photoresist layer. However, any suitable photoresist may be used for the photoresist layer. Next, the photoresist layer is exposed to a light pattern, such as an ultraviolet (UV), a far ultraviolet (FUV), or an extreme ultraviolet (EUV) exposure. A photomask may be used to create a light pattern by placing the photomask between the semiconductor structure 100 and a light source (not illustrated). In response to the exposure to the light pattern, a photoreaction may occur in exposed regions of the photoresist layer, while unexposed regions remain unchanged. As a result of the photoreaction, the exposed regions may comprise a cross-linked photoresist film, which may have material properties substantially different from the unreacted portion of the photoresist layer. Such a difference in the material properties includes volatility, reactivity, and/or solubility among others, which gives origin to the tonality as a photoresist.

After exposure to the light pattern, a development process is performed on the photoresist layer with a reactive precursor. In some embodiments, the development process is a plasma-less process performed with a gaseous (non-ionized) reactive precursor (also referred to as a developing gas). The reactive precursor reacts with, e.g., the unexposed regions of the photoresist layer to produce volatile by-products, which then evaporate from the surface of the semiconductor structure 100 to form an opening. This reaction develops the photoresist layer into a patterned photoresist layer. In some embodiments, the reactive precursor is a reactive gas such as hydrogen bromide (HBr), hydrogen chloride (HCl), boron trichloride (BCl₃), organic acids such carboxylic acids, methanol, ethanol, isopropyl alcohol, the like, or a mixture or combination thereof.

Next, the patterned photoresist layer is used as an etch mask to form the opening 116 through the second hardmask layer 114 and the second dielectric layer 112 with a suitable wet or dry etching process (e.g., an RIE process or the like using anisotropic plasma etching). After forming the opening 116 through the second hardmask layer 114, any remaining portions of the patterned photoresist layer (and any underlying layers of a lithography stack, if present) are removed with a suitable process, such as an ashing, a CMP, an etch back, or the like. However, any suitable techniques can be used to form the opening 116. In various embodiments, the opening 116 has a width in a range of 6 nm to 30 nm and a depth in a range of 6 nm to 100 nm.

FIGS. 3 through 7 illustrate a deposition-etch-deposition (DED) process for filling the opening 116 with a conductive material (e.g., ruthenium), in accordance with some embodiments. The deposition-etch-deposition process fills the opening 116 to form a conductive via while removing nuclei or clusters formed over the top surface of the semiconductor structure 100 outside of the opening 116 (such as over the second hardmask layer 114). This may be advantageous for forming conductive vias without using a subsequent planarization process (e.g., a CMP) that may create surface topological issues such as dishing. The DED process may be performed in a suitable process chamber, such as a plasma process chamber suitable for deposition and etching processes.

FIGS. 3 and 4 illustrate a first cycle of the DED process, in accordance with some embodiments. In FIG. 3, a first conductive layer 120A is formed in the opening 116. In various embodiments, the first conductive layer 120A comprises ruthenium and is formed with a suitable process such as chemical vapor deposition (CVD). This is a deposition step (also referred to as a CVD step) in the deposition-etch-deposition (DED) process for filling the opening 116. The first conductive layer 120A may be formed directly on (or in other words, in direct physical contact with) the underlying conductive feature 104. As such, a formation of an adhesion or liner layer between the conductive feature 104 and the first conductive layer 120A is omitted in some embodiments. This may be advantageous for reducing resistivity between the conductive feature 104 and the subsequently formed conductive via in the opening 116.

In some embodiments, the first conductive layer 120A is formed through the thermal decomposition of a ruthenium-containing precursor gas on the surface of the substrate. In various embodiments, ruthenium precursors used include organometallic compounds such as bis(ethylcyclopentadienyl)ruthenium (Ru(EtCp)₂), tris(2,2,6,6-tetramethyl-3,5-heptanedionato)ruthenium (Ru(tmhd)₃), or ruthenium carbonyl (Ru₃(CO)₁₂). The precursor gas is carried to the substrate surface by a carrier gas, such as carbon monoxide, argon, nitrogen, the like, or a combination thereof. In some embodiments, the deposition process is performed under a pressure of 5 mTorr to 750 mTorr, at a temperature range of 40° C. to 400° C., for a duration of 120 seconds to 600 seconds. In various embodiments, the first conductive layer 120A is formed to a thickness in a range of 3 nm to 20 nm.

In one or more embodiments, ruthenium is deposited using a thermal CVD process that utilizes a ruthenium carbonyl precursor, for example, triruthenium dodecacarbonyl (Ru₃(CO)₁₂). The ruthenium carbonyl precursor, Ru₃(CO)₁₂, is a solid at room temperature. In various embodiments, it may be heated in a precursor container to a temperature in the range of 60° C. to 100° C. to generate sufficient vapor pressure. The vaporized precursor is then carried into the deposition chamber using a carrier gas, such as carbon monoxide, argon, or nitrogen. Using carbon monoxide as a carrier gas may reduce premature decomposition of Ru₃(CO)₁₂ in the precursor container. This may allow for increased delivery of the precursor to the substrate as described by, for example, U.S. Pat. No. 7,270,848, which is incorporated by reference herein in its entirety. The flow rate of the carrier gas may be controlled to achieve the desired precursor partial pressure in the chamber.

When the vaporized Ru₃(CO)₁₂ molecules come into contact with the heated surface, they undergo thermal decomposition. The deposition chamber may be maintained at a temperature in the range of 40° C. to 400° C. The chamber pressure may be regulated in the range of 5 mTorr to 750 mTorr to ensure predetermined precursor decomposition and film growth rates. Throughout the process, the gaseous byproducts of the reaction are continuously removed from the chamber by the flow of carrier gas and the chamber's vacuum system.

In addition to the first conductive layer 120A formed in the opening 126, conductive nuclei 122 (also referred to as conductive clusters, ruthenium nuclei, or ruthenium clusters) may be formed over the top surface of the semiconductor structure 100, such as on the second hardmask layer 114, in the same process that forms the first conductive layer 120A. These conductive nuclei 122 may cause issues with subsequent manufacturing or deposition processes. As such, it is advantageous to remove the conductive nuclei 122. In various embodiments, the conductive nuclei 122 are isolated from each other on the second hardmask layer 114, and are also referred to as isolated nuclei or isolated clusters. In various embodiments, the conductive nuclei 122 may comprise a cluster of atoms of varying sizes and shapes and typically comprise a same crystalline structure (as opposed to a polycrystalline material potentially formed when adjacent nuclei merge together to form a continuous layer).

Next, in FIG. 4, an etch process is performed to remove the conductive nuclei 122. This may be advantageous for avoiding issues with subsequent manufacturing or deposition processes. The etch process is an etch step in the deposition-etch-deposition (DED) process for filling the opening 116. The etch process to remove the conductive nuclei 122 may be a dry etch performed in situ with the previous deposition of the first conductive layer 120A. Although not illustrated, the etch process may also remove a top portion of the first conductive layer 120A.

In some embodiments, the etching process includes a dry etch (e.g., a reactive ion etch (RIE)) performed with oxygen (O₂), nitrogen (N₂), hydrogen (H₂), a mixture of nitrogen and hydrogen (N₂/H₂), a mixture of nitrogen, oxygen, and hydrogen (N₂/O₂/H₂), a fluorine-containing gas (e.g., CF₄, C₄F₆, C₄F₈, CH₂F₂, CH₃F, CHF₃), a chlorine-based or bromine-based gas (Cl₂, HBr), the like, or a combination thereof. In some embodiments, the dry etch is performed under a pressure of 5 mTorr to 750 mTorr, at a temperature in a range of 100° C. to 200° C., for a duration of less than 60 seconds, with a plasma power measured at the power supply in a range of 100 W to 1500 W and a bias power in a range of 0 W to 100 W.

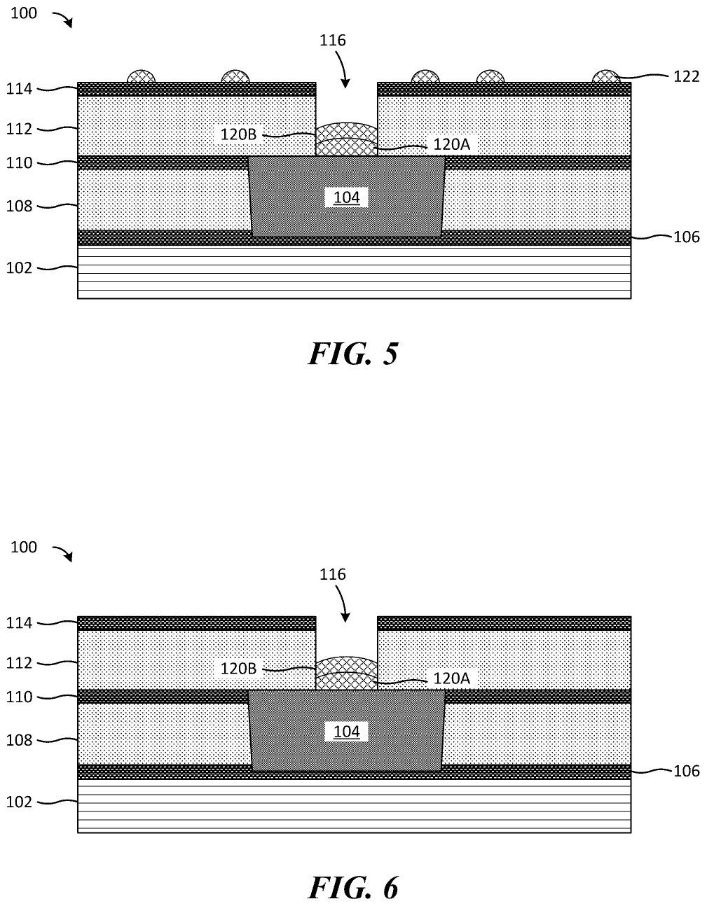

FIGS. 5 and 6 illustrate a second cycle of the DED process, in accordance with some embodiments. In FIG. 5, following from FIG. 4, a second conductive layer 120B is formed over the first conductive layer 120A in the opening 116. This is another deposition step in the deposition-etch-deposition (DED) process for filling the opening 116. The second conductive layer 120B may be formed using similar materials and methods as the first conductive layer 120A as described above with respect to FIG. 3, and the details are not repeated herein. The process to form the second conductive layer 120B may form additional conductive nuclei 122 over the top surface of the semiconductor structure 100, such as on the second hardmask layer 114.

Next, in FIG. 6, another etch process is performed to remove the additional conductive nuclei 122. The etch process may be performed using methods as described above with respect to FIG. 4, and the details are not repeated herein. This may be advantageous for avoiding issues with subsequent manufacturing or deposition processes. This etch process is another etch step in the deposition-etch-deposition (DED) process for filling the opening 116.

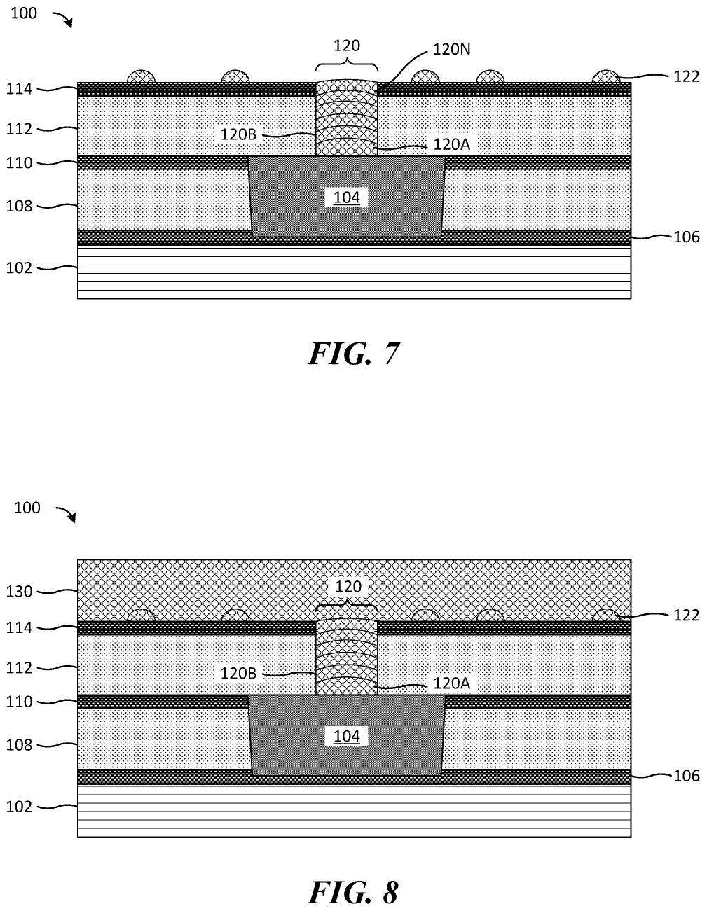

FIG. 7 illustrates the semiconductor structure 100 after the opening 116 has been filled by a conductive stack 120 (also referred to as a filled opening or filled hole) comprising conductive layers 120A through 120N. Each deposition step of forming an additional conductive layer of the conductive stack 120 (such as described with respect to FIGS. 3 and 5) may be followed by an etch step to remove conductive nuclei 122 (such as described with respect to FIGS. 4 and 6). In some embodiments, as illustrated by FIG. 7, a final deposition step (also referred to as a later deposition step) to form the conductive layer 120N is not followed by an etch step and the conductive nuclei 122 may remain. However, in other embodiments (see below, FIG. 13), the final deposition step is followed by a final etch step (also referred to as a later etch step) to remove the conductive nuclei 122.

As illustrated by FIG. 7, the conductive stack 120 comprises six conductive layers 120A, 120B, up to 120N. As such, the conductive stack 120 and semiconductor structure 100 illustrated by FIG. 7 may be formed with a deposition-etch-deposition (DED) process having six deposition steps alternating with five etch steps. However, any suitable number of conductive layers may be formed to fill the opening 116 with any suitable numbers of deposition and etch steps, and all such combinations are within the scope of the disclosed embodiments.

FIGS. 8 through 11 illustrate the formation of a conductive feature over the conductive stack 120 with a subtractive process, in accordance with some embodiments. In FIG. 8, following from FIG. 7, a conductive layer 130 (also referred to as a blanket layer) is formed over the second hardmask layer 114, the conductive stack 120, and the conductive nuclei 122 (if present). In various embodiments, the conductive layer 130 is formed with a field deposition using a suitable process, such as chemical vapor deposition (CVD), physical vapor deposition (PVD), the like, or a combination thereof. In one or more embodiments, the conductive layer 130 comprises ruthenium. The conductive layer 130 may be formed to a thickness in a range of 10 nm to 150 nm. In some embodiments, the conductive layer 130 directly physically contacts the conductive stack 120.

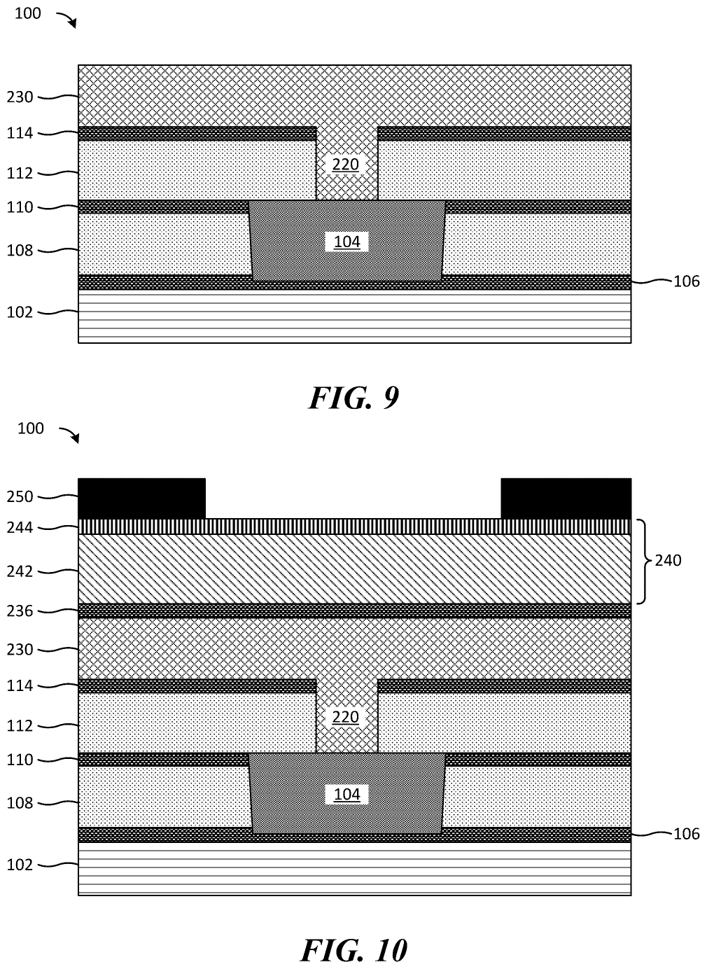

Next, in FIG. 9, the conductive material of the conductive layer 130 and the underlying conductive stack 120 are annealed, which may be advantageous for reducing surface oxidation of the conductive layer 130. The anneal may also cause merging and/or elimination of boundaries, if any, between the conductive layer 130, the conductive layers of the conductive stack 120, and the conductive nuclei 122 (if present). This may convert the conductive stack 120 into a conductive via 220 and also convert the conductive layer 130 and the conductive nuclei 122 into a conductive layer 230. The conductive via 220 and the conductive layer 130 may have fewer internal boundaries, or be free of internal boundaries, due to the anneal. In various embodiments, the anneal is performed with a suitable gas such as hydrogen (H₂) or the like. The anneal may be performed at a temperature in a range of 350° C. to 450° C., such as 400° C.

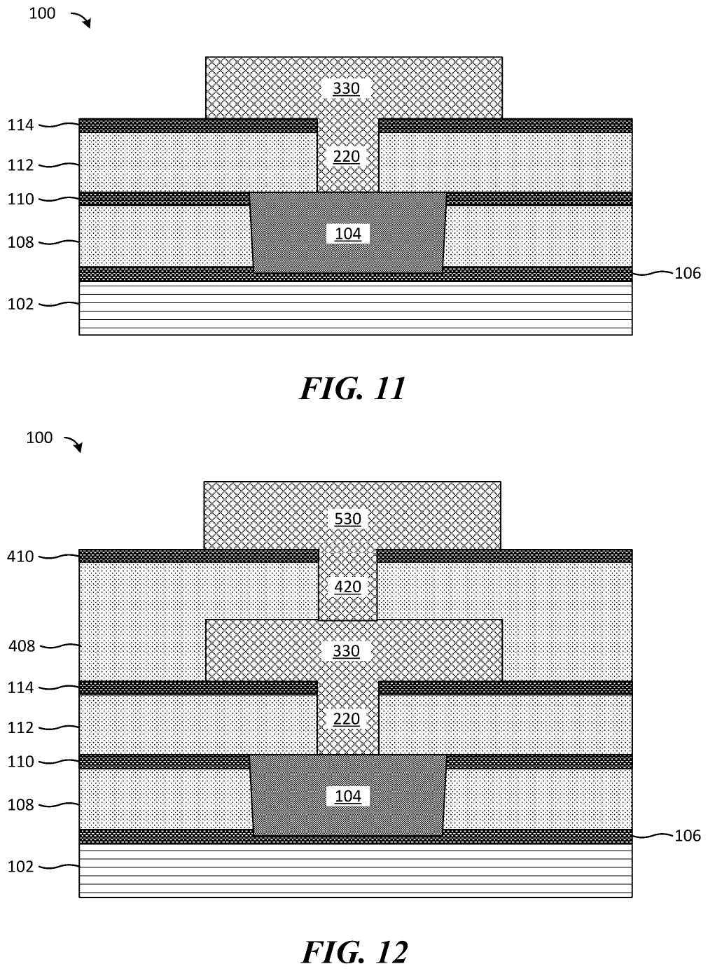

In FIG. 10, following from FIG. 9, a third hardmask layer 236, a lithography stack 240, and a patterned resist 250 are formed over the conductive layer 230. The third hardmask layer 236, the lithography stack 240, and the patterned resist 250 are used to pattern the conductive layer 230 to form a conductive feature (see below, FIG. 11) with a subtractive process. The third hardmask layer 236 may be formed using similar materials and methods as the first hardmask layer 110 as described above with respect to FIG. 1, and the details are not repeated herein. However, any suitable materials and methods may be used to form the third hardmask layer 236.

The lithography stack 240 comprises a planarizing layer 242 over the third hardmask layer 236 and an antireflective coating 244 over the planarizing layer 242. In some embodiments, the planarizing layer 242 comprises spin-on carbon (SOC), an organic planarizing layer (OPL), amorphous carbon, or the like. In some embodiments, the antireflective coating 244 comprises a bottom antireflective coating (BARC) such as a silicon antireflective coating (SiARC), an organic BARC, SiC, spin-on glass (SOG), silicon, silicon oxide, silicon nitride, or the like. However, any suitable materials may be used for the lithography stack 240, including the planarizing layer 242 and the antireflective coating 244.

A patterned resist 250 is formed over the lithography stack 240. The patterned resist 250 is used for the subsequent patterning of the conductive layer 230 (see below, FIG. 11). In some embodiments, the patterned resist 250 is a metal oxide resist that is exposed with extreme ultraviolet (EUV) radiation and developed with a wet etch selective to either exposed or unexposed regions of the metal oxide resist. In various embodiments, the patterned resist 250 comprises tin (Sn), antimony (Sb), hafnium (Hf), zirconium (Zr), zinc (Zn), the like, or a combination thereof. In certain embodiments, the patterned resist 250 comprises a metal oxide, a metal alkoxide, or a methacrylate (MAA) of Sn, Sb, Hf, Zr, Zn, or the like. In other embodiments, the patterned resist 250 is a photoresist that does not include metal oxide, e.g., a photopolymeric photoresist. However, any suitable photoresist, exposure method, and development method may be used to form the patterned resist 250.

Next, in FIG. 11, the conductive layer 230 is patterned to form a conductive feature 330 over the conductive via 220 with a subtractive process (also referred to as a patterning process). Although one conductive feature 330 is illustrated in FIG. 11, any suitable number of conductive features 330 with any suitable positions and dimensions may be formed. In some embodiments, the conductive feature 330 is formed with a multi-step etching process. For example, the patterned resist 250 may be used as an etch mask to pattern a portion of the lithography stack 240 with a suitable wet or dry etching process (e.g., an RIE process or the like using anisotropic plasma etching). The patterned portion of the lithography stack 240 is then used as an etch mask to etch the remaining portion of the lithography stack 240. Next, the remaining portion of the lithography stack 240 is used as an etch mask to pattern the third hardmask layer 236. The patterned portion of the third hardmask layer 236 is then used as an etch mask to pattern the conductive layer 230 and form a conductive feature 330. After forming the conductive feature 330, any remaining portions of the patterned resist 250, the lithography stack 240, and the third hardmask layer 236 are removed with a suitable process, such as a CMP, an etch back, or the like.

In FIG. 12, following from FIG. 11, a third dielectric layer 408 is formed over the conductive feature 330, a fourth hardmask layer 410 is formed over the third dielectric layer 408, a conductive via 420 is formed through the fourth hardmask layer 410 and the third dielectric layer 408, and a conductive feature 530 is formed over the conductive via 420 with a subtractive process. The third dielectric layer 408 may be formed using similar materials and methods as the first dielectric layer 108 as described above with respect to FIG. 1, and the details are not repeated herein. However, any suitable materials and methods may be used to form the third dielectric layer 408. The fourth hardmask layer 410 may be formed using similar materials and methods as the first hardmask layer 110 as described above with respect to FIG. 1, and the details are not repeated herein. However, any suitable materials and methods may be used to form the fourth hardmask layer 410.

The conductive via 420 is then formed through the fourth hardmask layer 410 and the third dielectric layer 408 to physically contact a top surface of one conductive feature 330. The conductive via 420 may be formed using similar materials and methods as the conductive via 220 as described above with respect to FIGS. 3-9, and the details are not repeated herein. Although the conductive via 420 is illustrated in the same cross-section of the semiconductor structure 100 as the conductive feature 330 for simplicity of illustration, it should be understood that the conductive vias 320 and 420 may be spaced apart in different cross-sections of the semiconductor structure 100, and any such relative positions of the conductive vias 320 and 420 are within the scope of the disclosed embodiments.

Next, a conductive feature 530 is formed over the conductive via 420. The conductive feature 530 may be formed using similar materials and methods as the conductive feature 330 as described above with respect to FIGS. 8-11, and the details are not repeated herein. Any suitable number of additional conductive vias and conductive features in any suitable number of interconnect layers may be subsequently formed over the semiconductor structure 100, and all such combinations and arrangements are within the scope of the disclosed embodiments.

FIGS. 13 through 17 illustrate cross-sectional views of another semiconductor structure 600 including a liner layer between the conductive via and the conductive feature formed with a subtractive process at intermediate stages of a semiconductor manufacturing process, in accordance with some embodiments. The semiconductor structure 600 as illustrated in FIG. 13 may be manufactured using similar methods and materials as the semiconductor structure 100 as described above with respect to FIGS. 1-7, and the details are not repeated herein. In FIG. 13, an additional etch process is performed to remove the conductive nuclei 122 (see above, FIG. 7). This etch process is an additional etch step performed after the deposition-etch-deposition (DED) process for filling the opening 116 as illustrated in FIGS. 3-7. The etch process may be performed using methods as described above with respect to FIG. 4, and the details are not repeated herein. This may be advantageous for avoiding issues with subsequent manufacturing or deposition processes such as the formation of a liner layer (see below, FIG. 14).

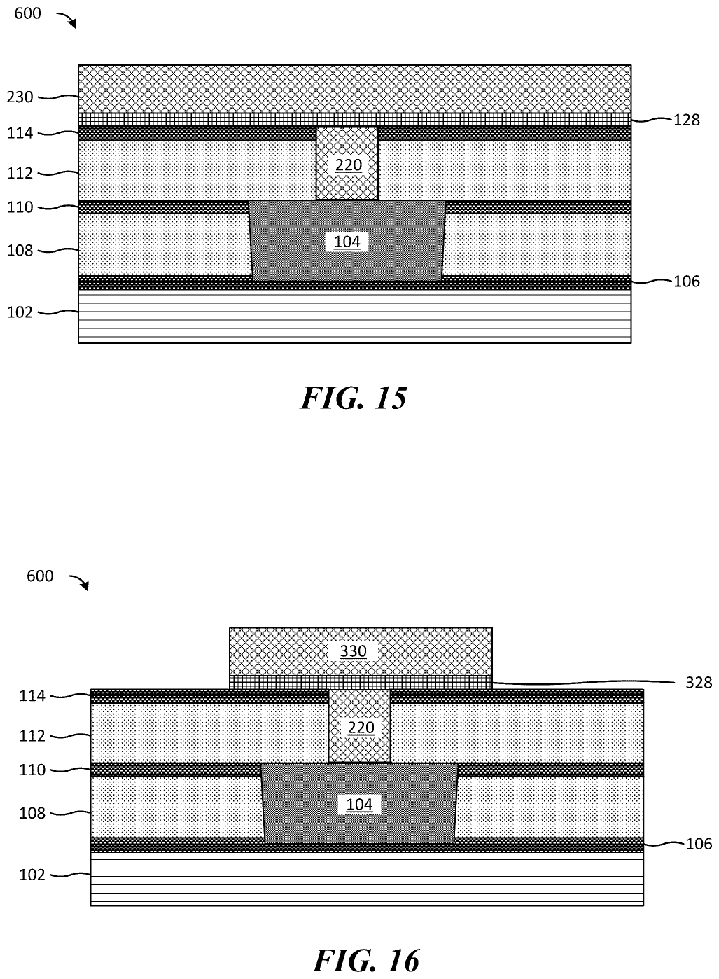

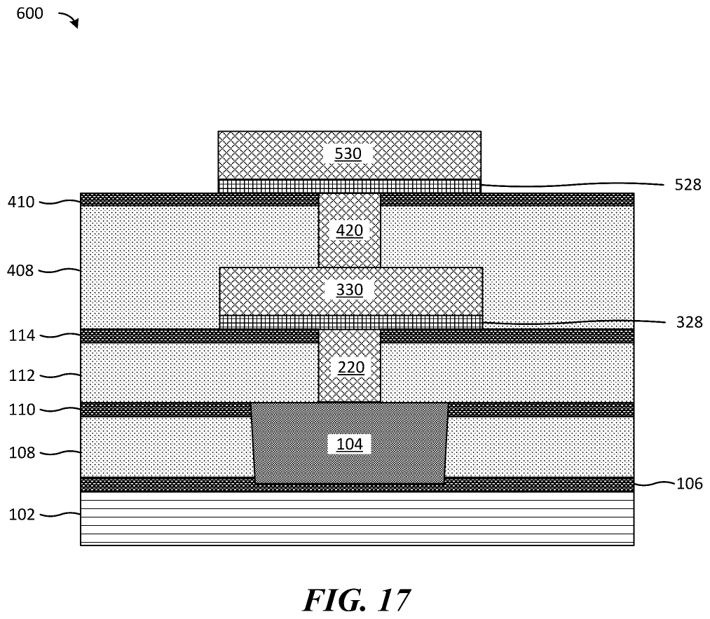

Next, in FIG. 14, a liner layer 128 is formed over the conductive stack 120 and the second hardmask layer 114 and a conductive layer 130 is formed over the liner layer 128. The liner layer 128 may be advantageous for achieving better adhesion between a dielectric surface (e.g., the second hardmask layer 114) and a subsequently formed conductive feature (see below, FIG. 16). In various embodiments, the liner layer 128 comprises a suitable material such as a metal nitride (e.g., titanium nitride (TiN), tantalum nitride (TaN), the like, or a combination thereof), a metal oxide (titanium oxide (TiO), aluminum oxide (AlO)_or the like), a pure metal (e.g., tungsten (W), titanium (Ti), cobalt (Co), tantalum (Ta), molybdenum (Mo), nickel (Ni), niobium (Nb), the like, or a combination thereof), the like, or a combination thereof. The liner layer 128 may be formed with chemical vapor deposition (CVD), physical vapor deposition (PVD), electroplating, electroless plating, the like, or a combination thereof. However, any suitable material and method may be used to form the liner layer 128.

The conductive layer 130 is then formed over the liner layer 128. The conductive layer 130 may be formed using similar materials (e.g., ruthenium) and methods as described above with respect to FIG. 8, and the details are not repeated herein.

In FIG. 15, following from FIG. 14, the conductive material of the conductive layer 130 and the underlying conductive stack 120 are annealed, which may be advantageous for reducing surface oxidation of the conductive layer 130. The anneal may also cause merging and/or elimination of boundaries, if any, between the conductive layers of the conductive stack 120. This may convert the conductive stack 120 into a conductive via 220 and also convert the conductive layer 130 and the conductive nuclei 122 into a conductive layer 230. The conductive via 220 and the conductive layer 130 may have fewer internal boundaries, or be free of internal boundaries, due to the anneal. The anneal may be performed using similar methods as described above with respect to FIG. 9, and the details are not repeated herein.

Next, in FIG. 16, the liner layer 128 and the conductive layer 230 are patterned with a subtractive process to form a conductive feature 330 and a liner 328 over the conductive via 220. The conductive feature 330 may be formed using similar methods as described above with respect to FIGS. 10-11, with the addition of further etching through the liner layer 128 to form the liner 328 between the conductive feature 330 and the underlying conductive via 220 and second hardmask layer 114. As such, the details are not repeated herein.

In FIG. 17, following from FIG. 16, a third dielectric layer 408 is formed over the conductive feature 330, a fourth hardmask layer 410 is formed over the third dielectric layer 408, a conductive via 420 is formed through the fourth hardmask layer 410 and the third dielectric layer 408, and a liner 528 and conductive feature 530 are formed over the conductive via 420 with a subtractive process. The third dielectric layer 408 may be formed using similar materials and methods as the first dielectric layer 108 as described above with respect to FIG. 1, and the details are not repeated herein. However, any suitable materials and methods may be used to form the third dielectric layer 408. The fourth hardmask layer 410 may be formed using similar materials and methods as the first hardmask layer 110 as described above with respect to FIG. 1, and the details are not repeated herein. However, any suitable materials and methods may be used to form the fourth hardmask layer 410.

The conductive via 420 is then formed through the fourth hardmask layer 410 and the third dielectric layer 408 to physically contact a top surface of one conductive feature 330. The conductive via 420 may be formed using similar materials and methods as the conductive via 220 as described above with respect to FIGS. 3-9, and the details are not repeated herein. Although the conductive via 420 is illustrated in the same cross-section of the semiconductor structure 100 as the conductive via 320 for simplicity of illustration, it should be understood that the conductive vias 320 and 420 may be spaced apart in different cross-sections of the semiconductor structure 600, and any such relative positions of the conductive vias 320 and 420 are within the scope of the disclosed embodiments.

Next, a liner 528 and conductive feature 530 is formed over the conductive via 420. The liner 528 and the conductive feature 530 may be formed using similar materials and methods as the liner 328 and conductive feature 330 as described above with respect to FIGS. 14-16, and the details are not repeated herein. Any suitable number of additional conductive vias and conductive features in any suitable number of interconnect layers may be subsequently formed over the semiconductor structure 600, and all such combinations and arrangements are within the scope of the disclosed embodiments. Additionally, although FIG. 17 illustrates liners between respective conductive vias and conductive features, it should be understood that liners may be present or absent between any respective pair of conductive via and conductive feature, and all such combinations are within the scope of the disclosed embodiments.

FIG. 18 illustrates a process flow chart diagram of a method 800 for forming an interconnect structure, in accordance with some embodiments. In step 802, a hole through a dielectric layer is filled with ruthenium using a deposition-etch-deposition (DED) process as described above with respect to FIGS. 3-7. One or more etch steps of the DED process removes isolated ruthenium nuclei deposited over the dielectric layer by deposition steps of the DED process.

In step 804, a ruthenium layer is formed over the dielectric layer as described above with respect to FIGS. 8-9. In step 806, a conductive feature is formed from the ruthenium layer with a subtractive process, as described above with respect to FIGS. 10-11.

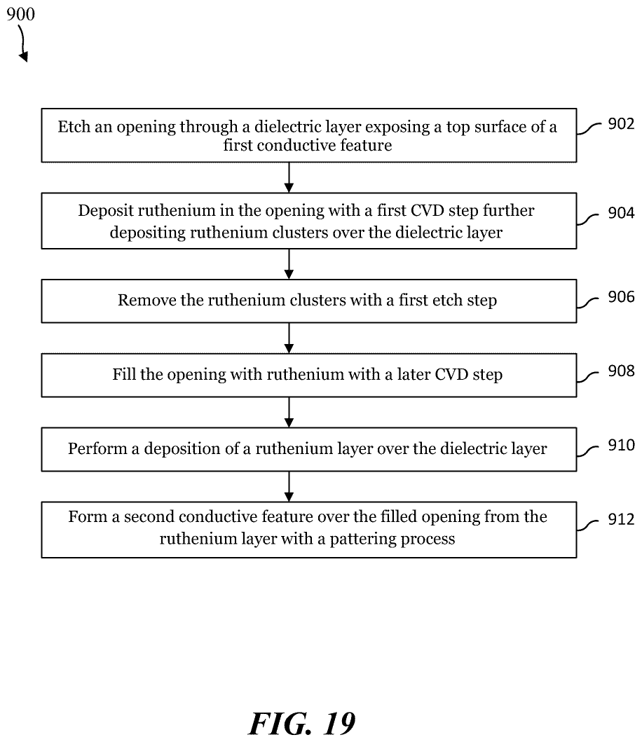

FIG. 19 illustrates a process flow chart diagram of a method 900 for forming an interconnect structure, in accordance with some embodiments. In step 902, an opening is etched through a dielectric layer, as described above with respect to FIG. 2. The opening exposes a top surface of a first conductive feature.

In step 904, ruthenium is deposited in the opening with a first chemical vapor deposition (CVD) step, as described above with respect to FIG. 3. The first CVD step further depositing ruthenium clusters over the dielectric layer. In step 906, removing the ruthenium clusters with a first etch step, as described above with respect to FIG. 4.

In step 908, the opening is filled with ruthenium with a later CVD step, as described above with respect to FIG. 7. In step 910, a deposition of a ruthenium layer is performed over the dielectric layer, as described above with respect to FIG. 8. In step 912, a second conductive feature is formed from the ruthenium layer with a patterning process, as described above with respect to FIGS. 10-11. The second conductive feature is over the filled opening.

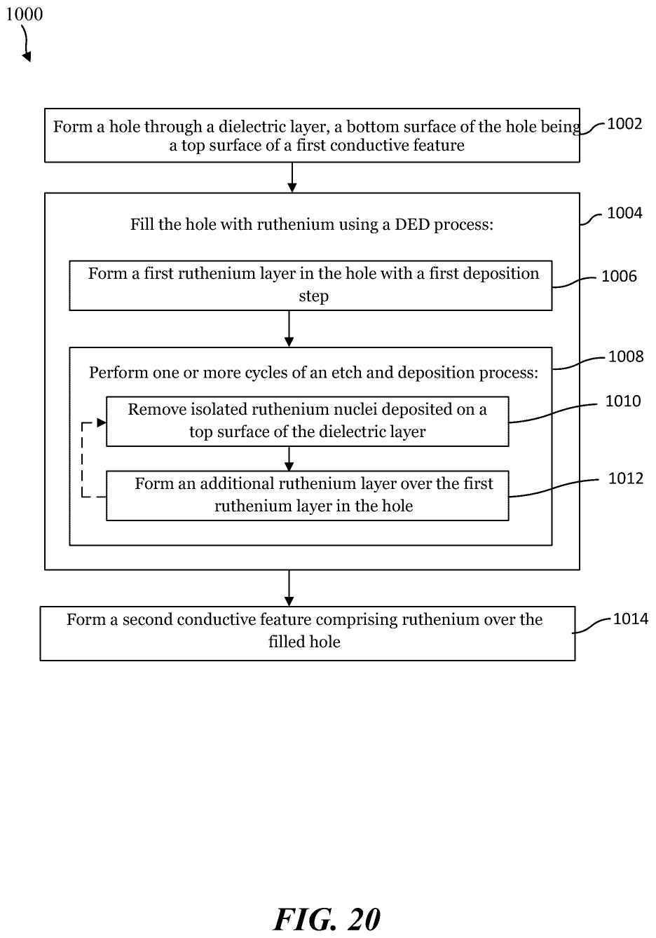

FIG. 20 illustrates a process flow chart diagram of a method 1000 for forming an interconnect structure, in accordance with some embodiments. In step 1002, a hole is formed through a dielectric layer, as described above with respect to FIG. 2. A bottom surface of the hole is a top surface of a first conductive feature

In step 1004, the hole is filled with ruthenium using a deposition-etch-deposition (DED) process, as described with respect to FIGS. 3-7. The DED process comprises steps 1006 and 1008. In step 1006, a first ruthenium layer is formed in the hole with an initial deposition step, as described above with respect to FIG. 3.

In step 1008, one or more cycles of an etch and deposition process are performed. Each cycle comprises steps 1010 and 1012. In step 1010, isolated ruthenium nuclei deposited on a top surface of the dielectric layer by a previous deposition step are removed with an etch step, as described above with respect to FIG. 4. In step 1012, an additional ruthenium layer is formed over the first ruthenium layer in the hole with a deposition step, as described above with respect to FIG. 5.

Following step 1004, step 1014 is performed. In step 1014, a second conductive feature comprising ruthenium is formed over the filled hole, as described above with respect to FIGS. 8-11.

Example embodiments of the disclosure are summarized here. Other embodiments can also be understood from the entirety of the specification as well as the claims filed herein.

Example 1. A method for forming an interconnect structure, the method including: filling a hole through a dielectric layer with ruthenium using a deposition-etch-deposition (DED) process, one or more etch steps of the DED process removing isolated ruthenium nuclei deposited over the dielectric layer by deposition steps of the DED process; forming a ruthenium layer over the dielectric layer; and forming a conductive feature from the ruthenium layer with a subtractive process.

Example 2. The method of example 1, where the conductive feature is over the filled hole.

Example 3. The method of one of examples 1 or 2, further including forming a liner layer over the dielectric layer and the filled hole before forming the ruthenium layer.

Example 4. The method of example 3, where the liner layer includes a metal nitride, a metal oxide, or a pure metal.

Example 5. The method of one of examples 3 or 4, further including removing isolated ruthenium nuclei with another etch step after filling the hole and before forming the liner layer.

Example 6. The method of one of examples 1 or 2, where the conductive feature physically contacts the filled hole.

Example 7. The method of one of examples 1 to 6, further including annealing the ruthenium layer and the filled hole.

Example 8. A method for forming an interconnect structure, the method including: etching an opening through a dielectric layer, the opening exposing a top surface of a first conductive feature; depositing ruthenium in the opening with a first chemical vapor deposition (CVD) step, the first CVD step further depositing ruthenium clusters over the dielectric layer; removing the ruthenium clusters with a first etch step; filling the opening with ruthenium with a later CVD step; performing a deposition of a ruthenium layer over the dielectric layer; and forming a second conductive feature from the ruthenium layer with a patterning process, the second conductive feature being over the filled opening.

Example 9. The method of example 8, further including depositing ruthenium in the opening with a second CVD step between the first etch step and the later CVD step.

Example 10. The method of example 9, further including removing ruthenium clusters deposited over the dielectric layer with a second etch step between the second CVD step and the later CVD step.

Example 11. The method of one of examples 8 to 10, further including removing ruthenium clusters deposited over the dielectric layer with a later etch step after the later CVD step.

Example 12. The method of example 11, further including forming a liner layer over the filled opening and the dielectric layer after the later etch step.

Example 13. The method of one of examples 8 to 10, where the ruthenium deposited in the opening physically contacts the first conductive feature.

Example 14. The method of one of examples 8 to 13, further including performing an anneal on the ruthenium layer.

Example 15. A method for forming an interconnect structure, the method including: forming a hole through a dielectric layer, a bottom surface of the hole being a top surface of a first conductive feature; filling the hole with ruthenium using a deposition-etch-deposition (DED) process, the DED process including: forming a first ruthenium layer in the hole with an initial deposition step; and performing one or more cycles of an etch and deposition process, each cycle including: removing isolated ruthenium nuclei deposited on a top surface of the dielectric layer by a previous deposition step with an etch step; and forming an additional ruthenium layer over the first ruthenium layer in the hole with a deposition step; and forming a second conductive feature including ruthenium over the filled hole.

Example 16. The method of example 15, further including, after filling the hole using the DED process, removing isolated ruthenium nuclei from the top surface of the dielectric layer with an additional etch step.

Example 17. The method of example 16, further including forming a liner layer over the filled hole before forming the second conductive feature.

Example 18. The method of example 17, where the liner layer includes titanium nitride or tantalum nitride.

Example 19. The method of example 15, where the second conductive feature directly physically contacts the filled hole.

Example 20. The method of one of examples 15 to 19, where forming the second conductive feature includes: forming a blanket layer including ruthenium; annealing the blanket layer; and patterning the blanket layer.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for forming an interconnect structure, the method comprising:
filling a hole through a dielectric layer with ruthenium using a deposition-etch-deposition (DED) process, one or more etch steps of the DED process removing isolated ruthenium nuclei deposited over the dielectric layer by deposition steps of the DED process;
forming a ruthenium layer over the dielectric layer; and
forming a conductive feature from the ruthenium layer with a subtractive process.

2. The method of claim 1, wherein the conductive feature is over the filled hole.

3. The method of claim 1, further comprising forming a liner layer over the dielectric layer and the filled hole before forming the ruthenium layer.

4. The method of claim 3, wherein the liner layer comprises a metal nitride, a metal oxide, or a pure metal.

5. The method of claim 3, further comprising removing isolated ruthenium nuclei with another etch step after filling the hole and before forming the liner layer.

6. The method of claim 1, wherein the conductive feature physically contacts the filled hole.

7. The method of claim 1, further comprising annealing the ruthenium layer and the filled hole.

8. A method for forming an interconnect structure, the method comprising:
etching an opening through a dielectric layer, the opening exposing a top surface of a first conductive feature;
depositing ruthenium in the opening with a first chemical vapor deposition (CVD) step, the first CVD step further depositing ruthenium clusters over the dielectric layer;
removing the ruthenium clusters with a first etch step;
filling the opening with ruthenium with a later CVD step;
performing a deposition of a ruthenium layer over the dielectric layer; and
forming a second conductive feature from the ruthenium layer with a patterning process, the second conductive feature being over the filled opening.

9. The method of claim 8, further comprising depositing ruthenium in the opening with a second CVD step between the first etch step and the later CVD step.

10. The method of claim 9, further comprising removing ruthenium clusters deposited over the dielectric layer with a second etch step between the second CVD step and the later CVD step.

11. The method of claim 8, further comprising removing ruthenium clusters deposited over the dielectric layer with a later etch step after the later CVD step.

12. The method of claim 11, further comprising forming a liner layer over the filled opening and the dielectric layer after the later etch step.

13. The method of claim 8, wherein the ruthenium deposited in the opening physically contacts the first conductive feature.

14. The method of claim 8, further comprising performing an anneal on the ruthenium layer.

15. A method for forming an interconnect structure, the method comprising:
forming a hole through a dielectric layer, a bottom surface of the hole being a top surface of a first conductive feature;
filling the hole with ruthenium using a deposition-etch-deposition (DED) process, the DED process comprising:
forming a first ruthenium layer in the hole with an initial deposition step; and
performing one or more cycles of an etch and deposition process, each cycle comprising:
removing isolated ruthenium nuclei deposited on a top surface of the dielectric layer by a previous deposition step with an etch step; and
forming an additional ruthenium layer over the first ruthenium layer in the hole with a deposition step; and
forming a second conductive feature comprising ruthenium over the filled hole.

16. The method of claim 15, further comprising, after filling the hole using the DED process, removing isolated ruthenium nuclei from the top surface of the dielectric layer with an additional etch step.

17. The method of claim 16, further comprising forming a liner layer over the filled hole before forming the second conductive feature.

18. The method of claim 17, wherein the liner layer comprises titanium nitride or tantalum nitride.

19. The method of claim 15, wherein the second conductive feature directly physically contacts the filled hole.

20. The method of claim 15, wherein forming the second conductive feature comprises:
forming a blanket layer comprising ruthenium;
annealing the blanket layer; and
patterning the blanket layer.
